(19) United States
(12) Patent Application Publication
(10) Pub. No.: US 2014/0011310 A1
(43) Pub. Date: Jan. 9, 2014

(54) METHOD OF MANUFACTURING SEMICONDUCTOR LIGHT EMITTING DEVICE

(71) Applicant: SAMSUNG ELECTRONICS CO., LTD., Suwon-si (KR)

(72) Inventors: Seok Min HWANG, Suwon-si (KR); Jae Yoon KIM, Yongin (KR); Je Won KIM, Yongin (KR); In Bum YANG, Yongin (KR); In Yong HWANG, Hwaseong (KR)

(21) Appl. No.: 13/921,872

(22) Filed: Jun. 19, 2013

(30) Foreign Application Priority Data
Jul. 5, 2012 (KR) 10-2012-0073510

(51) Int. Cl. H01L 33/00

(52) U.S. Cl. CPC H01L 33/0095
USPC 438/33

(57) ABSTRACT

A method of manufacturing a semiconductor light emitting device is provided. The method includes irradiating a laser into a substrate having a first surface and a second surface opposing each other to form at least one laser irradiation area on the substrate. A light emitting structure including a first conductive semiconductor layer, an active layer, and a second conductive semiconductor layer is formed on the substrate. The light emitting structure and the substrate is cut in a position corresponding to the laser irradiation area of the substrate, in a top surface of the light emitting structure, to separate the light emitting structure and the substrate into individual device units.

### CROSS-REFERENCE TO RELATED APPLICATION

This application claims the priority of Korean Patent Application No. 10-2012-0073510 filed on Jul. 5, 2012, in the Korean Intellectual Property Office, the disclosure of which is incorporated herein by reference.

### TECHNICAL FIELD

The disclosure relates to a method of manufacturing a semiconductor light emitting device (LED).

### BACKGROUND

A semiconductor light emitting device such as a light emitting diode, a device in which materials contained therein emit light through the application of electrical energy, may convert energy generated through the recombination of electrons and electron holes in a junction semiconductor into light to be emitted. Light emitting diodes are widely used in lighting devices and displays and as lighting sources, and the development thereof has therefore been accelerated.

In particular, recently, the development and employment of gallium nitride-based LEDs has increased, and mobile device keypads, vehicle turn signal lamps, camera flashes, and the like, using such a gallium nitride-based LED, have been commercialized, and, in line with this, the development of general illumination devices using LEDs has accelerated. Like the products to which they are applied, such as a backlight unit of a large TV, a vehicle headlamp, a general illumination device, and the like, products in which LEDs are utilized are gradually moving toward large-sized products having high outputs and high efficiency, and thus, the characteristics of LEDs used in such products are required to satisfy the high level of the characteristics required of the LEDs.

### SUMMARY

An aspect of the disclosure provides a method of manufacturing a semiconductor light emitting device capable of reducing a size of an area removed from a light emitting structure and a semiconductor layer of a substrate in a scribing process, in which the light emitting structure and the substrate are cut to be separated into individual devices, as compared to the related art, in which an excessively large area is removed in order to cut the light emitting structure and the substrate and separate individual devices, causing considerable loss of the light emitting structure and the substrate.

According to an aspect of the disclosure, there is provided a method of manufacturing a semiconductor light emitting device, the method including irradiating a laser into a substrate having a first surface and a second surface opposing each other to form at least one laser irradiation area in the substrate. A light emitting structure is formed on the substrate including a first conductive semiconductor layer, an active layer, and a second conductive semiconductor layer. The light emitting structure and the substrate are cut in a top surface of the light emitting structure in a position corresponding to the laser irradiation area of the substrate to separate the light emitting structure and the substrate into individual device units.

In certain embodiments, the laser irradiation area may be formed in an interior of the substrate. The laser irradiation area may be formed in an area of the substrate. The irradiation area is removed when the light emitting structure and the substrate are cut to be separated into the individual device units.

In certain embodiments, the laser irradiation area may be formed so as to isolate the individual device units from each other.

In certain embodiments, the laser irradiation area may be formed at a depth of 0.5 to 20 μm from the first surface of the substrate. The laser irradiation area may be formed to have a length of 5 to 100 μm in certain embodiments.

In certain embodiments, the laser irradiation area may be formed by continuous laser irradiation, or in other embodiments, the laser irradiation area may be formed by intermittent laser irradiation.

The substrate may have prominences and depressions formed on the first surface thereof in certain embodiments.

The method may further include in certain embodiments: lapping the second surface of the substrate before the cutting of the light emitting structure and the substrate to separate the light emitting structure and the substrate into individual device units.

In the lapping of the second surface of the substrate, a thickness of the substrate may decrease to 80 to 400 μm.

According to another aspect of the disclosure, a method of manufacturing a semiconductor light emitting device is provided. The method comprises irradiating laser beam into a substrate having a first surface and a second surface opposing each other to form at least a laser irradiation area in the substrate. A light emitting structure including an active layer on the substrate having the laser irradiation area is formed.

The method may further comprise a step of separating the light emitting structure into individual device units.

According to another aspect of the disclosure, a method of manufacturing a semiconductor light emitting device is provided. The method comprises selectively irradiating a semiconductor substrate with laser radiation. The laser radiation is focused in the substrate at a depth L1 from a first surface of the substrate to form a laser irradiation area. A light emitting structure including a first conductive semiconductor layer, an active layer, and a second conductive semiconductor layer is formed on the substrate. The light emitting structure and the substrate are cut at a position corresponding to the laser irradiation area of the substrate to separate the light emitting structure and the substrate into individual device units.

### BRIEF DESCRIPTION OF THE DRAWINGS

The above and other aspects, features and other advantages of the disclosure will be more clearly understood from the following detailed description taken in conjunction with the accompanying drawings, in which:

FIGS. 1 through 6 are schematic views illustrating a method of manufacturing a semiconductor light emitting device according to an embodiment of the disclosure;

FIG. 7 is an enlarged view of part A of FIG. 1; and

FIG. 8 is an enlarged view of part B of FIG. 5.

### DETAILED DESCRIPTION

Hereinafter, embodiments of the disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey its scope to those skilled in the art. In the drawings, the shapes and dimensions of elements may be exaggerated for clarity, and the same reference numerals will be used throughout to designate the same or like elements.

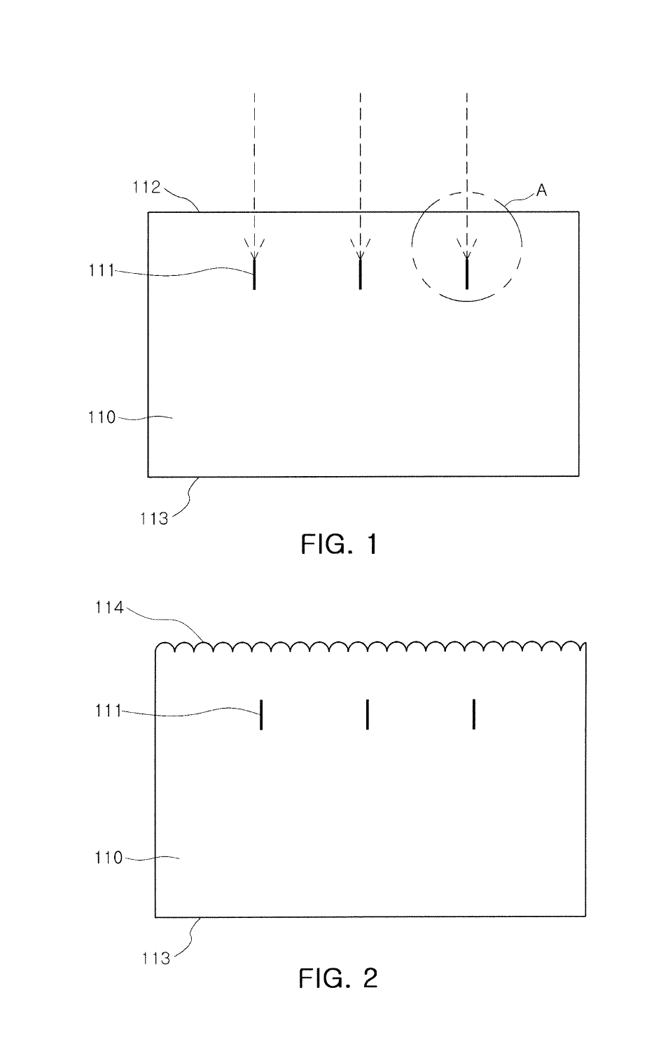

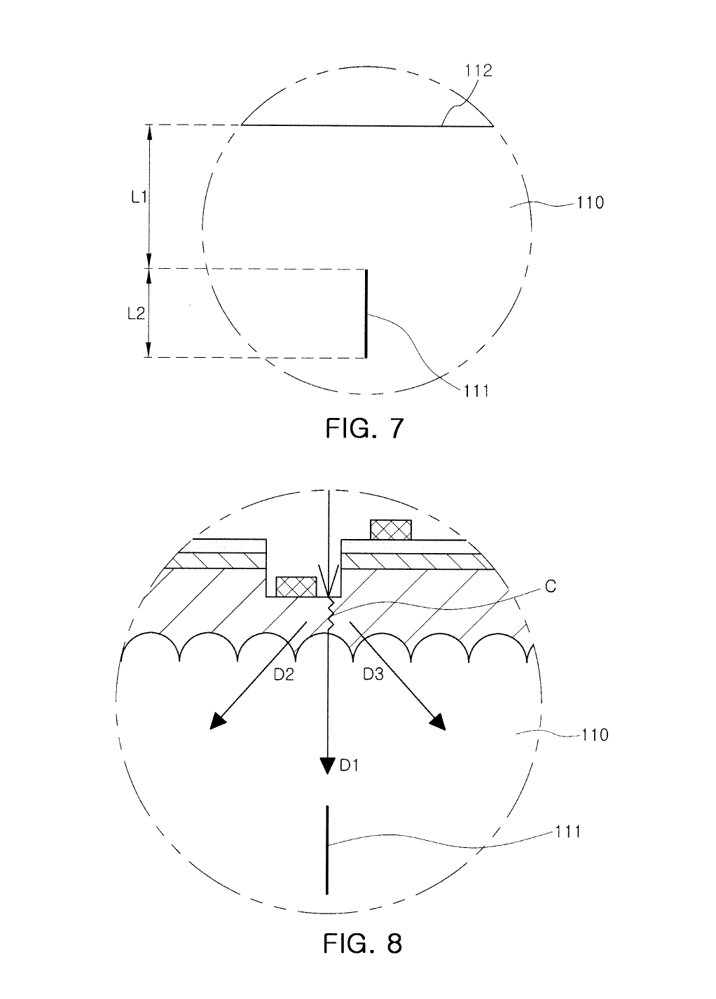

FIGS. 1 through 6 are schematic views illustrating a method of manufacturing semiconductor light emitting devices 100 according to an embodiment of the disclosure. FIG. 7 is an enlarged view of part A of FIG. 1

First, a laser is irradiated into the interior of a substrate 110 having a first surface 112 and a second surface 113 to form a laser irradiation area 111 in the interior of the substrate 110. The first surface 112 may be a main surface of the substrate 110 and the second surface 113 maybe a rear surface thereof.

The substrate 110 may be a substrate for growing a semiconductor single crystal, especially, a nitride single crystal. Specifically, a substrate made of a material such as sapphire, silicon (Si), zinc oxide (ZnO), gallium arsenide (GaAs), silicon carbide (SiC),MgAl₂O₄,MgO, LiAlO₂, LiGaO₂, GaN, or the like, may be used as the substrate 110. In this case, sapphire is a crystal having Hexa-Rhombo R3c symmetry, of which lattice constants in c-axis and a-axis directions are 13.001 Å and 4.758 Å, respectively. A sapphire crystal has a C-plane (0001), an A-plane (1120), an R-plane (1102), and the like. In certain embodiments, a nitride thin film can be relatively easily formed on the C-plane of the sapphire crystal. Because sapphire crystal is stable at high temperatures it is commonly used as a material for a nitride growth substrate. In addition, a thickness of the substrate may be approximately 640 μm in the embodiment of the inventive subject matter.

In certain embodiments, at least one laser irradiation area 111 may be formed in the interior of the substrate 110.

The laser irradiation area 111 is a portion of a crystal structure of the substrate 110, deformed due to thermal energy of a laser when the laser is irradiated into the substrate 110.

In certain embodiments, the laser may be a laser having a relatively long wavelength, such as, for example, a stealth laser having a wavelength of approximately 800˜1200 nm.

In certain embodiments, the stealth laser may be an LD excitation solid-state laser. Alternatively, the stealth laser may be a YAG laser having a light source wavelength of 1064 nm. In addition, the stealth laser may have a frequency of 400 kHz, and a laser spot having an output of 1W or less and a diameter of 1 to 2 μm may be used therefor. Moreover, a laser oscillator may be a high repetition rate oscillator, and a movement velocity of laser light maybe approximately 300 mm/s.

The laser irradiation area 111 may be formed by focusing and irradiating the stealth laser into the interior of the substrate 110.

In certain embodiments, the laser irradiation area 111 is an area formed by heating and melting the substrate 110 using a laser. The crystal structure of the melted portion may be deformed into an amorphous structure during a cooling process. Since the amorphous structure may tend to be damaged, the laser irradiation area 111 may be used as a base point for dividing the substrate 110 into device units, that is, the semiconductor light emitting devices 100.

In certain embodiments, the laser irradiation area 111 is formed in an area of the substrate. The laser irradiation area is divided into the semiconductor light emitting devices 100 by cutting the light emitting structure 120 and the substrate 110 and then exerting impacts thereon, whereby the light emitting structure 120 and the substrate 110 may be easily divided into the semiconductor light emitting devices 100.

As shown in FIG. 7, the laser irradiation area 111 may formed at a predetermined depth L1 from the first surface 112 of the substrate 110 and have a predetermined length L2. The laser irradiation area 111 may be formed at a depth in the substrate 110 and have a length such that the substrate 110 is not exposed, even in the case that the rear surface of the substrate 110 is subjected to a machining process.

In this case, the laser irradiation area 111 may be formed at the depth L1 of 0.5 to 20 μm from the first surface 112 of the substrate 110 and have a length of 5 to 100 μm between the first surface 112 and the second surface 113 of the substrate 110.

In addition, the laser irradiation area 111 may have a continuous linear shape by continuous laser irradiation, and may have a discontinuous spot shape by intermittent laser irradiation.

Moreover, as shown in FIG. 2, fine prominences and depressions 114 may be formed on the first surface 112 of the substrate 110 to form a patterned sapphire substrate (PSS) . The PSS may reduce a phenomenon in which light emitted from an active layer 122 of the light emitting structure 120 is totally reflected from the surface of the substrate 110. Furthermore, since a laser is irradiated into the substrate 110 and then, the fine prominences and depressions 114 are formed thereon, damage of the fine prominences and depressions 114 due to the laser may be prevented.

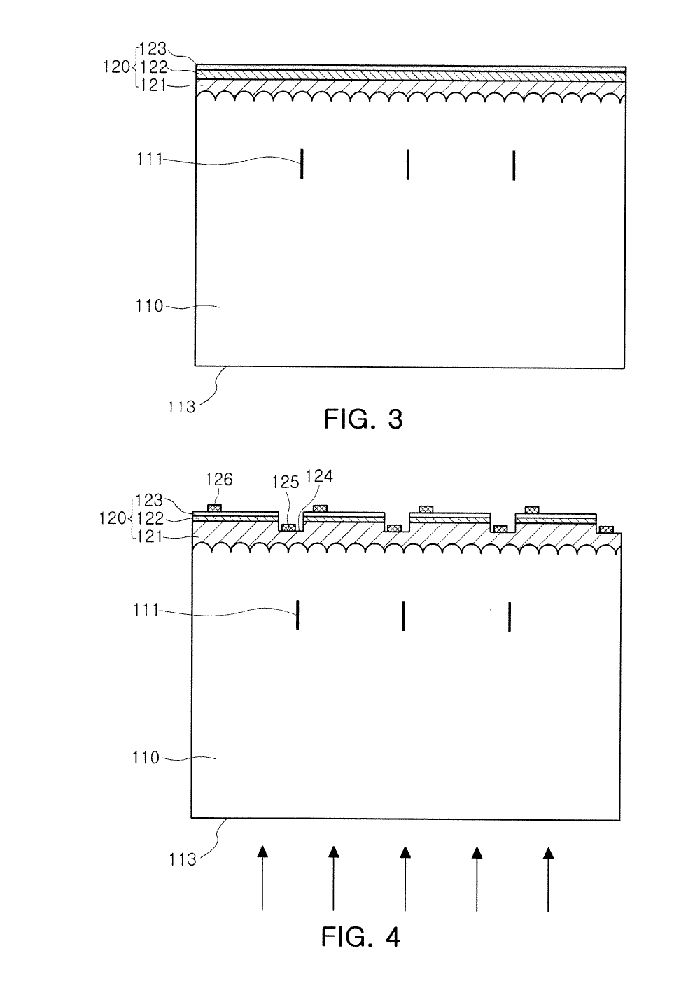

As illustrated in FIG. 3, a first conductive semiconductor layer 121, the active layer 122, and a second conductive semiconductor layer 123 are subsequently laminated on the substrate 110 to form the light emitting structure 120.

The first and second conductive semiconductor layers 121 and 123 may be made of a nitride semiconductor, namely, a semiconductive material doped with an n-type impurity and a p-type impurity having a compositional formula AlₓIn_{y}Ga_{1-x-y)}N (here, 0≦x≦1, 0≦y≦1, 0≦x+y≦1), and the semiconductive material may be, typically, GaN, AlGaN, and InGaN. Silicon (Si), germanium (Ge), selenium (Se), tellurium (Te), or the like, may be used as the n-type impurity, and manganese (Mg), zinc (Zn), beryllium (Be), or the like, may be used as the p-type impurity. The first and second conductive semiconductor layers 121 and 123 may be grown through a process commonly known in the art, such as metal-organic chemical vapor deposition (MOCVD), molecular beam epitaxy (MBE), hydride vapor phase epitaxy (HVPE), or the like.

The active layer 122 is formed between the first conductive semiconductor layer 121 and the second conductive semiconductor layer 123. The active layer 122 has a multi-quantum well (MQW) structure in which quantum well layers and quantum barrier layers are alternately laminated. For example, the active layer 122 has an MQW structure in which quantum well layers and quantum barrier layers of AlₓIn_{y}Ga_{1-x-y)}N (0≦x≦1, 0≦y≦1, 0≦x+y≦1) are alternately laminated to have a certain band gap, and electrons and holes may be recombined by the quantum well structure to emit light. The active layer 122 may be grown through a process such as metal-organic chemical vapor deposition (MOCVD), molecular beam epitaxy (MBE), hydride vapor phase epitaxy (HVPE), or the like, known in the art, in the same manner as the first and second conductive semiconductor layers 121 and 123.

Meanwhile, although not shown, in certain embodiments, before the first conductive semiconductor layer 121 is formed, a buffer layer may be formed on the substrate 110. The buffer layer may be formed to alleviate a difference between lattice constants of the substrate 110 and the first conductive semiconductor layer 121. In the present embodiment, a gallium nitride layer may be used as the buffer layer.

Thereafter, as illustrated in FIG. 4, a mesa surface 124 may be formed on a certain area of the light emitting structure 120 including a top portion of the laser irradiation area 111, to separate the light emitting structure 120 into the semiconductor light emitting devices 100 and isolate the semiconductor light emitting devices 100 from each other, and first and second electrodes 125 and 126 are respectively formed on the first and second conductive semiconductor layers 121 and 123. The mesa surface 124 may be formed using an appropriate etching process known in the related art, such as an inductively coupled plasma reactive ion etching (ICPRIE) method or the like.

In certain embodiments, the method of manufacturing a semiconductor light emitting device may further include lapping the substrate 110 to reduce a thickness thereof. The lapping process is intended to decrease sizes of the semiconductor light emitting devices 100 and improve heat radiation performance thereof by reducing the thickness of the substrate 110 included in the semiconductor light emitting devices 100, final products, and may be undertaken on the second surface 113 of the substrate 110. Specifically, the lapping process may reduce the thickness of the substrate 110 to 80 to 400 μm. However, the lapping process is not necessarily required and may be omitted as long as the thickness of the substrate 110 is originally provided to be relatively small.

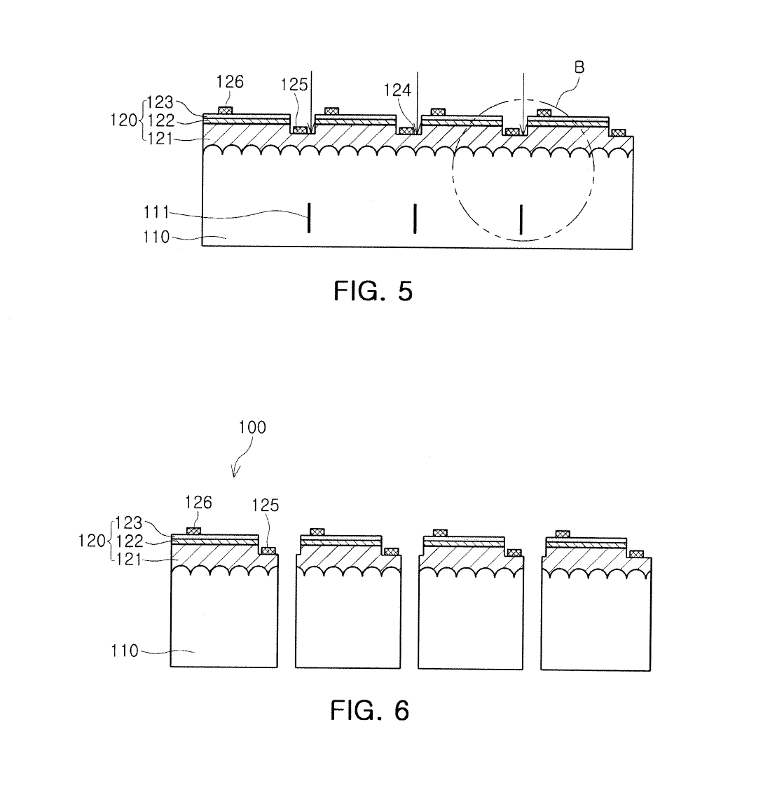

As illustrated in FIG. 5, when a scribing process of separating the individual semiconductor light emitting devices 100 by exerting pressure on the top portion of the laser irradiation area 111 is undertaken, the semiconductor light emitting devices 100 are manufactured as shown in FIG. 6.

The scribing process is a process, in which a crack C, occurring when the light emitting structure 120 and the laser irradiation area 111 are damaged by exerting pressure on the top portion of the laser irradiation area 111, propagates to the second surface 113 of the substrate 110 from the first surface 112 thereof to thereby separate the individual semiconductor light emitting devices 100.

FIG. 8 is an enlarged view of part B of FIG. 5 and illustrates a process in which the crack C propagates. The crack C may diagonally propagate (D2 or D3) in a crystal direction, rather than propagating in a vertical direction, due to crystallinity of the substrate 110. When the crack C propagates diagonally as described above, chipping defects in which portions of the substrate 110 are damaged in the semiconductor light emitting devices 100 may be generated. In order to prevent the chipping defects, a method of enlarging a distance between the semiconductor light emitting devices 100 has been used in the related art. When the distance between the semiconductor light emitting devices 100 is enlarged, even in the case in which the crack C propagates diagonally, since the crack propagation occurs within the area to be removed at the time of separating the device units, chipping defects may be prevented.

However, when the distance between the semiconductor light emitting devices 100 is enlarged, the amount of an area removed from the light emitting structure 120 and the substrate 110 during a manufacturing process increases simultaneously with the enlargement of the distance, such that manufacturing costs increase and a light emitting area of the semiconductor light emitting devices 100 may relatively decrease.

According to a certain embodiment, the laser irradiation area 111 is formed in the interior of the substrate 110. Thus, even in the case in which the crack C propagates diagonally (D2 or D3) due to crystallinity of the substrate 110, the crack C propagates to the laser irradiation area 111 which is vertically formed (D1), such that the diagonally propagating crack C may propagate in the vertical direction. Thus, the semiconductor light emitting devices 100 having the above configuration may allow for a reduced distance between the semiconductor light emitting devices 100 during a manufacturing process thereof. Specifically, the distance between the semiconductor light emitting devices 100 may be reduced to 10 μm or less.

In a similar manner, when the distance between the semiconductor light emitting devices 100 is reduced, the amount of loss from the semiconductor light emitting devices during a scribing process may be reduced, and due to the reduction, effects of enlarging the light emitting area of semiconductor light emitting devices 100 manufactured using a substrate having the area equal to that of the related art may be obtained.

For example, when the semiconductor light emitting devices 100 each have a size of 290 μm×500 μm on the substrate 110, it is considered that the loss range of 20 μm occurs in boundaries between the individual light emitting devices 100 during a scribing process according to the related art; however, the loss range may be reduced to 10 μm according to an embodiment of the disclosure.

In a certain embodiment, a semiconductor light emitting device of the related art may have a size of 270 μm×480 μm and consequently, has an area of 129,600 μm², while the semiconductor light emitting device according to the embodiment has an increased size to 280 μm×490 μm, and consequently, has an area of 137,200 μm². Thus, a light emitting area increase of approximately 5.9% may be obtained by applying the presently disclosed method to the related art manufacturing process.

When a distance between the first surface 112 of the substrate 110 and the laser irradiation area 111 exceeds 50 μm, the diagonally propagating crack C (D2 or D3) is excessively large before arriving at the laser irradiation area 111, making it difficult to propagate the crack C to the laser irradiation area 111, such that the effects of changing the ongoing direction of the diagonally propagating crack C into the vertical direction may be reduced.

In addition, since the laser irradiation area 111 is formed in the substrate 110 before the light emitting structure 120 is grown according to certain embodiments of the disclosure, defects in which the semiconductor layer of the light emitting structure 120 is subjected to thermal damage due to laser and destroyed or the brightness thereof is reduced may be prevented in advance.

Moreover, the method according to the certain embodiments of the disclosure may be applied to vertical type semiconductor light emitting devices as well as horizontal type semiconductor light emitting devices.

As set forth above, according to certain embodiments of the disclosure, the method of manufacturing a semiconductor light emitting device may reduce a size of an area removed from the light emitting structure and the substrate in a scribing process in which the light emitting structure and the substrate are cut to be separated into individual devices, to thereby decrease manufacturing costs.

While the disclosure has been shown and described in connection with the embodiments, it will be apparent to those skilled in the art that modifications and variations can be made without departing from the spirit and scope of the disclosure as defined by the appended claims.

What is claimed is:

1. A method of manufacturing a semiconductor light emitting device, the method comprising:
irradiating a laser into a substrate having a first surface and a second surface opposing each other to format least one laser irradiation area in the substrate;
forming a light emitting structure including a first conductive semiconductor layer, an active layer, and a second conductive semiconductor layer on the substrate;
cutting the light emitting structure and the substrate in a position corresponding to the laser irradiation area of the substrate, in a top surface of the light emitting structure, to separate the light emitting structure and the substrate into individual device units.

2. The method of claim 1, wherein the laser irradiation area is formed in an interior of the substrate.

3. The method of claim 1, wherein the laser irradiation area is formed in an area of the substrate, the area being removed when the light emitting structure and the substrate are cut to be separated into the individual device units.

4. The method of claim 3, wherein the laser irradiation area is formed to isolate the individual device units from each other.

5. The method of claim 1, wherein the laser irradiation area is formed at a depth of 0.5 to 20 μm from the first surface of the substrate.

6. The method of claim 1, wherein the laser irradiation area is formed to have a length of 5 to 100 μm.

7. The method of claim 1, wherein the laser irradiation area is formed by continuous laser irradiation.

8. The method of claim 1, wherein the laser irradiation area is formed by intermittent laser irradiation.

9. The method of claim 1, wherein the substrate has prominences and depressions formed on the first surface thereof.

10. The method of claim 1, further comprising: lapping the second surface of the substrate before the cutting of the light emitting structure and the substrate to separate the light emitting structure and the substrate into individual device units.

11. The method of claim 10, wherein in the lapping of the second surface of the substrate, a thickness of the substrate decreases to 80 to 400 μm.

12. A method of manufacturing a semiconductor light emitting device, the method comprising:
irradiating a laser beam into a substrate having a first surface and a second surface opposing each other to format least a laser irradiation area in the substrate; and
forming a light emitting structure including an active layer on the substrate having the laser irradiation area.

13. The method of manufacturing a semiconductor light emitting device according to claim 12, further comprising a step of separating the light emitting structure into individual device units.

14. A method of manufacturing a semiconductor light emitting device, the method comprising:
selectively irradiating a semiconductor substrate with laser radiation, wherein the substrate comprises a first surface and an opposing second surface, and laser radiation is focused in the substrate at a depth L1 from the first surface of the substrate to form a laser irradiation area;
forming a light emitting structure including a first conductive semiconductor layer, an active layer, and a second conductive semiconductor layer on the substrate;
cutting the light emitting structure and the substrate at a position corresponding to the laser irradiation area of the substrate to separate the light emitting structure and the substrate into individual device units.

15. The method of manufacturing a semiconductor light emitting device according to claim 14, wherein the laser radiation has a wavelength of approximately 800 to 1200 nm.

16. The method of manufacturing a semiconductor light emitting device according to claim 14, further comprising forming prominences and depressions on the first surface of the substrate prior to forming the light emitting structure.

17. The method of manufacturing a semiconductor light emitting device according to claim 14, further comprising forming a plurality of spaced-apart laser irradiation areas.

18. A method of manufacturing a semiconductor light emitting device according to claim 17, wherein at least three laser irradiation areas are formed and the laser irradiation areas are spaced apart by a substantially equal distance.

19. A method of manufacturing a semiconductor light emitting device according to claim 14, wherein the substrate comprises sapphire, Si, ZnO, GaAs, SiC, MgAl₂O₄, MgO, LiAlO₂, LiGaO₂, or GaN.

20. A method of manufacturing a semiconductor light emitting device according to claim 14, further comprising lapping the second surface of the substrate to reduce a thickness of the substrate before the cutting of the light emitting structure and the substrate.
